(19) United States
(12) Patent Application Publication
(10) Pub. No.: US 2011/0025360 A1
(43) Pub. Date: Feb. 3, 2011

(54) SEMICONDUCTOR INTEGRATED CIRCUIT TEST DEVICE

(75) Inventor: Hidehiko KURODA, Kanagawa (JP)

Correspondence Address: YOUNG & THOMPSON, 209 Madison Street, Suite 500, Alexandria, VA, 22314, US

(73) Assignee: RENESAS ELECTRONICS CORPORATION, Kanagawa (JP)

(21) Appl. No.: 12/838,967

(22) Filed: Jul. 19, 2010

(30) Foreign Application Priority Data
Aug. 3, 2009 (JP) 2009-180326

(51) Int. Cl. G01R 31/00; G01R 31/26

(52) U.S. Cl. 324/756.03; 324/762.01

(57) ABSTRACT

A semiconductor IC test device includes: an IC tester providing first and second control signals (CS1/CS2) based on a condition for qualifying a prescaler of a sorted semiconductor IC; and a probe card connected to the IC tester and the semiconductor IC. The probe card includes: a VCO (Voltage Controlled Oscillator) outputting a signal with frequency f based on CS1; a reference prescaler dividing f; a power variable device providing a signal with frequency f and a power based on CS2 to the sorted prescaler; a variable phase shifter canceling phase difference based on a difference between a path length through the reference prescaler versus sorted prescaler; and a conversion circuit section converting a signal based on a phase difference between a signal with a frequency divided by the sorted prescaler and a signal outputted from the reference prescaler, into a DC voltage, which is output to the IC tester.

### INCORPORATION BY REFERENCE

This application claims the benefit of priority based on Japanese Patent Publication No. 2009-180326, filed on Aug. 3, 2009, the disclosure of which is incorporated herein by reference.

### BACKGROUND OF THE INVENTION

1. Field of the Invention

The present invention relates to a semiconductor integrated circuit test device for testing a semiconductor integrated circuit and a semiconductor integrated circuit test method using this semiconductor integrated circuit test device, in particular, a semiconductor integrated circuit test device having a probe card and a semiconductor integrated circuit test method using this semiconductor integrated circuit test device.

2. Description of Related Art

In recent years, mobile communications ICs (Integrated Circuit) and RF (Radio Frequency) ICs have been highly integrated. As a result, many function circuits such as PLL (Phase-Locked Loop) frequency synthesizers and frequency conversion circuits have been incorporated into the ICs. For example, in some transmission/reception ICs for mobile phones and reception ICs for GPSs (Global Positioning System), all function circuits except for reference oscillators such as TCXOs (Temperature Compensated Xtal Oscillator) are integrated.

While the size of the semiconductor integrated circuit has increased year after year as described above, cost competition is severe and cost reduction is desired in terms of production. Accordingly, it is necessary to sort highly integrated circuits more reliably and rapidly. In order to reduce costs as much as possible, it is necessary to sort defective pieces at a stage prior to a manufacturing process, that is, a stage with small added value.

In a general RFIC manufacturing process, however, defective pieces in terms of DC (Direct Current) characteristics are removed by performing an on-wafer DC test after diffusion of a wafer. After that, non-defective pieces in terms of DC characteristics are passed to a package assembly step, and then, DC check is made again and finally, RF characteristic check as an AC (Alternative Current) operation check is made. As described above, the operation check of the RF circuit is made in the form of a packaged end product. That is, the operation check of the RF circuit is made with high costs. When the RF circuit is determined as the defective piece in this stage, this means poor efficiency in terms of price and disadvantageous measure for cost reduction.

To solve this problem, it is required to make the operation check in a wafer state in a stage with minimum manufacturing costs.

In this connection, Patent literature 1 (Japanese Patent Publication No. Heisei 1-194432A) discloses an integrated circuit chip sorter. In the integrated circuit chip sorter, a microwave oscillator 104, a power divider 105, a reference frequency divider 106 and a mixer 107 are mounted on a probe card 102 to perform on-wafer measurement of a frequency division circuit. The probe card 102 is connected to a measurement device (tester) 101 having a frequency counter therein by input/output sections 110, 111, 114 and 115. The probes 112, 113 and 116 are configured to be connected to a power source, an input terminal and an output terminal of the integrated circuit chip (frequency division circuit) to be sorted 103.

FIG. 1 is a circuit diagram for describing operations of the integrated circuit chip disclosed in Patent literature 1. First, the microwave oscillator 104 generates a signal having frequency and power for operation of the circuit divider to be sorted. The power divider 105 divides the signal into two signals. One of the two divided signals is sent to a frequency division circuit input section to be sorted, frequency divided by n by the frequency divider and inputted to a mixer 107 on the probe card 102. The other of the two divided signals is frequency divided by n by the reference frequency divider 106 on the probe card and supplied to the mixer.

Receiving inputs of the signals, the mixer 107 outputs following signals. When the inputted signals have the same frequency, that is, the frequency divider to be sorted normally operates and the same output signal frequency as that of the reference frequency divider 106 is obtained, the frequency of the output signal of the mixer 107 becomes 0 Hz. In other words, components of the output signal of the mixer 107 are only DC components. On the contrary, when the inputted signals have different frequencies, that is, the frequency divider to be sorted does not normally operate, the output signal of the mixer 107 is not DC and a signal in the IF (Intermediate Frequency) band is outputted.

When the frequency of these output signals is measured by the frequency counter built in the measurement device (tester) 101, the measurement result is 0 Hz for the non-defective piece and a given IF frequency for the defective piece. Whereby, the frequency divider to be sorted can be sorted in the on-wafer state. In other words, a prescaler circuit determines the quality of a piece by using the tester (AC tester) built in the frequency counter that determines whether the output frequency is 0 Hz or the predetermined IF frequency in one fixed frequency.

Patent literature 2 (Japanese Patent Publication No. Heisei 9-288149A) discloses a semiconductor integrated circuit frequency sorter. In the semiconductor integrated circuit frequency sorter, a VCO (Voltage Controlled Oscillator), an LPF (Low Pass Filter), a phase comparator, a frequency divider (Second embodiment) and a reference oscillator (Second embodiment) are mounted on the probe card to perform on-wafer measurement of the frequency division circuit. The sorter and the frequency divider to be measured constitute a phase lock loop circuit.

FIGS. 2A and 2B are circuit diagrams for describing operations of the semiconductor integrated circuit frequency sorter described in Patent literature 2. A reference frequency supplied from an IC tester (first embodiment) or a reference frequency inputted from the reference oscillator (second embodiment) on the probe card is compared with a frequency obtained by dividing a frequency of the VCO by the frequency divider to be sorted by use of the phase comparator. A phase difference signal obtained as a result of this comparison is converted into a voltage smoothed by the LPF. A feedback loop that controls the oscillating frequency of the VCO with the converted voltage is formed and acts as a phase lock loop.

At this time, the output voltage of the LPF is measured by the IC tester and the quality is determined based on the DC value obtained by the measurement. When the frequency divider to be sorted (N frequency division) normally operates, the VCO oscillates with a frequency that is N times as high as the reference frequency, and thus, the phase lock loop becomes stable and a certain DC voltage is outputted. When the frequency divider to be sorted (N frequency division) does not normally operate, the phase lock loop remains unstable and an output voltage of the LPF remains fixed at a lower limit or a higher limit. Consequently, the quality can be determined by determining these output voltages in a certain range (standard). That is, the prescaler circuit determines the quality of the piece by using the AC tester or the DC tester that determines whether the output voltage is a certain voltage value or the output lower limit or the output higher limit in one fixed frequency.

### Citation List

### [Patent Literature]

Patent Literature 1: Japanese Patent Publication No. Heisei 1-194432A

Patent Literature 2: Japanese Patent Publication No. Heisei 9-288149A

### SUMMARY OF THE INVENTION

As operation check of the integrated circuit, DC check or AC (RF) check can be used. Generally, in the DC check, an operational current or a terminal voltage is checked. In place of the AC check, in a differential circuit, a differential voltage is given to an input, respective potentials and potential difference of differential outputs are measured and a gain and a dynamic range of the differential circuit are checked in terms of DC to perform alternative sorting of the AC (RF) operation.

However, although the prescaler circuit, in particular, when built in the integrated circuit, is consisted of the differential circuit, it is generally constituted of a master slave-type flip flop circuit or the like. Thus, due to its operational principle, at power-on, the flip flop circuit is self-excited and performs a latch operation. For this reason, even if no input signal exists, the circuit self-oscillates. Thus, it is impossible to measure a terminal voltage in terms of DC and feed the input voltage and check the output voltage. As a result, it is difficult to determine whether or not the circuit normally operates in terms of DC.

Accordingly, the most that can be done as the operation check in the present circumstances is to apply a power source voltage in some stages and measure a circuit current at self-oscillation, and the check is mainly in an RF sorting step after package assembling. In such sorting, even when a circuit failure occurs in the manufacturing process (refer to FIG. 6), the quality cannot be determined by the time when the circuit takes the form of an end product, making cost reduction difficult. In order to reduce product costs, it is important to check all operations as much as possible in the on-wafer state after a diffusion step.

Thus, various methods have been proposed. For example, the above-mentioned two patents are cited as the conventional technique. Both patents disclose a configuration in which the AC circuit is formed on the probe card to perform the operation check in the on-wafer state after the diffusion step, the operation check of the prescaler to be sorted is performed and its quality is determined using the tester. However, according to the conventional technique, the prescaler to be sorted is checked based on only one point: one input frequency and one input power. For this reason, when it is attempted to check the prescaler in the used frequency range having the upper limit and the lower limit or a power range, it is necessary to further install the microwave oscillator and the reference oscillator, making the circuit configured on the probe card complicated. Furthermore, since the tester for determining the quality requires the frequency counter and a reference frequency generator, the operation check using only an inexpensive DC tester is difficult to be achieved.

In the former conventional example, the frequency counter of the tester is required and measurement cannot be made by using only a DC tester function. In the latter example, since an LPF output voltage of the phase lock loop is measured, measurement can be made by using only a DC tester. However, when it is attempted to make measurement with some input frequencies, the AC tester having an oscillator for supplying corresponding reference signal frequencies and an available signal source is required. When some reference frequencies are provided on the probe card, measurement can be made by using the DC tester, but the configured circuit becomes complicated. Furthermore, the sorting step is generally performed in a factory and many probers and handlers are operating in the surroundings. In such environment with high disturbing noises, when the phase lock is disconnected, the test cannot be normally performed.

A semiconductor integrated circuit test device of the present invention comprises: an IC tester configured to provide a first and a second control signals based on a condition for determining a quality of a prescaler of a semiconductor integrated circuit to be sorted; and a probe card connected to the IC tester and configured to connect with the semiconductor integrated circuit. The probe card comprises: a VCO (Voltage Controlled Oscillator) configured to output a signal with a given frequency based on the first control signal; a reference prescaler configured to divide the given frequency of the signal outputted from the VCO; a power variable device configured to provide a signal with the given frequency and a given power based on the second control signal to the prescaler to be sorted; a variable phase shifter configured to cancel a difference of phase based on a difference between a length of a path in which a signal passes through the reference prescaler and a length of a path in which a signal passes through the prescaler to be sorted; and a conversion circuit section configured to convert a signal based on a difference of phase between a signal with a frequency divided by the prescaler to be sorted and a signal outputted from the reference prescaler, into a DC voltage and output the DC voltage to the IC tester.

A semiconductor integrated circuit testing method of the present invention comprises: connecting a probe card with a semiconductor integrated circuit including a prescaler to be sorted; providing a first and a second control signal based on a condition for determining a quality of the prescaler to be sorted to the probe card; outputting a signal with a given frequency based on the first control signal; dividing the given frequency of the outputted signal by use of a reference prescaler of the probe card; providing a signal with the given frequency and a given power based on the second control signal to the prescaler to be sorted; dividing the given frequency of the provided signal by use of the prescaler to be sorted; cancelling a difference of phase based on a difference between a length of a path in which a signal passes through the reference prescaler and a length of a path in which a signal passes through the prescaler to be sorted; and converting a signal based on a difference of phase between a signal with a frequency divided by the prescaler to be sorted and a signal outputted from the reference prescaler, into a DC voltage.

A control terminal is connected to a DC tester that determines the quality, a measuring frequency and power can be varied by a voltage control oscillator (VCO) and a power variable device that are controlled by the application of a DC voltage and the output DC voltage converted by a peak hold circuit can be sorted by the IC tester (DC tester) only in terms of DC values. Furthermore, to adjust various frequency division ratios and phases of input signals and stably measure and sort the DC value, a variable phase shifter such as a delay line is provided, thereby enabling adjustment of the level of an output DC value. As a result, AC (RF) operation check with multi-frequency and multi-power that correspond to various deficient modes of a prescaler circuit can be performed in an on-wafer state as a stage of low manufacturing costs by using only the DC tester.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram for describing operations of an integrated circuit chip disclosed in Patent literature 1;

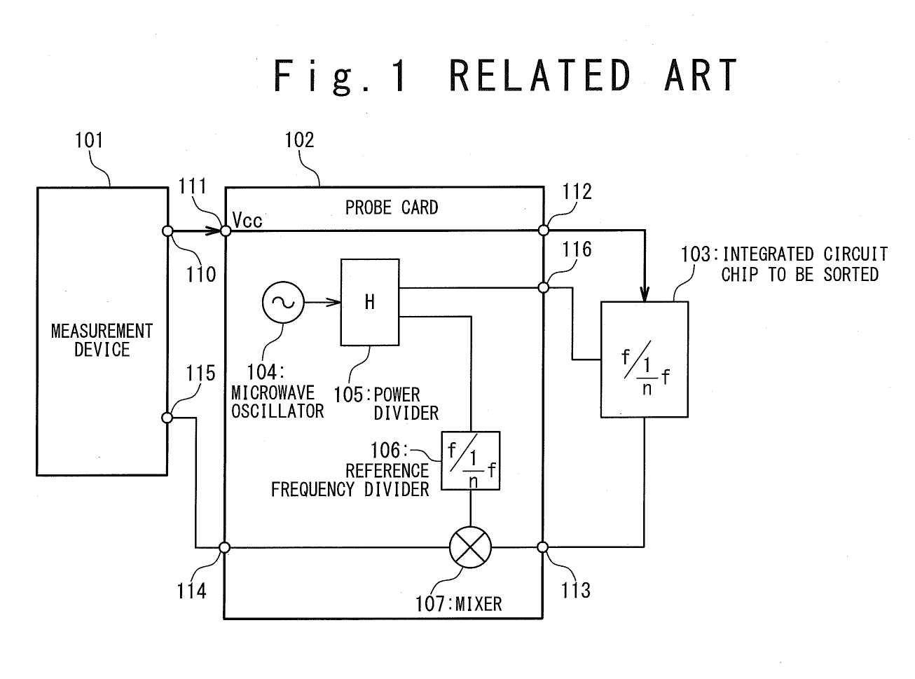

FIGS. 2A and 2B are circuit diagrams for describing operations of a semiconductor integrated circuit frequency sorter described in Patent literature 2;

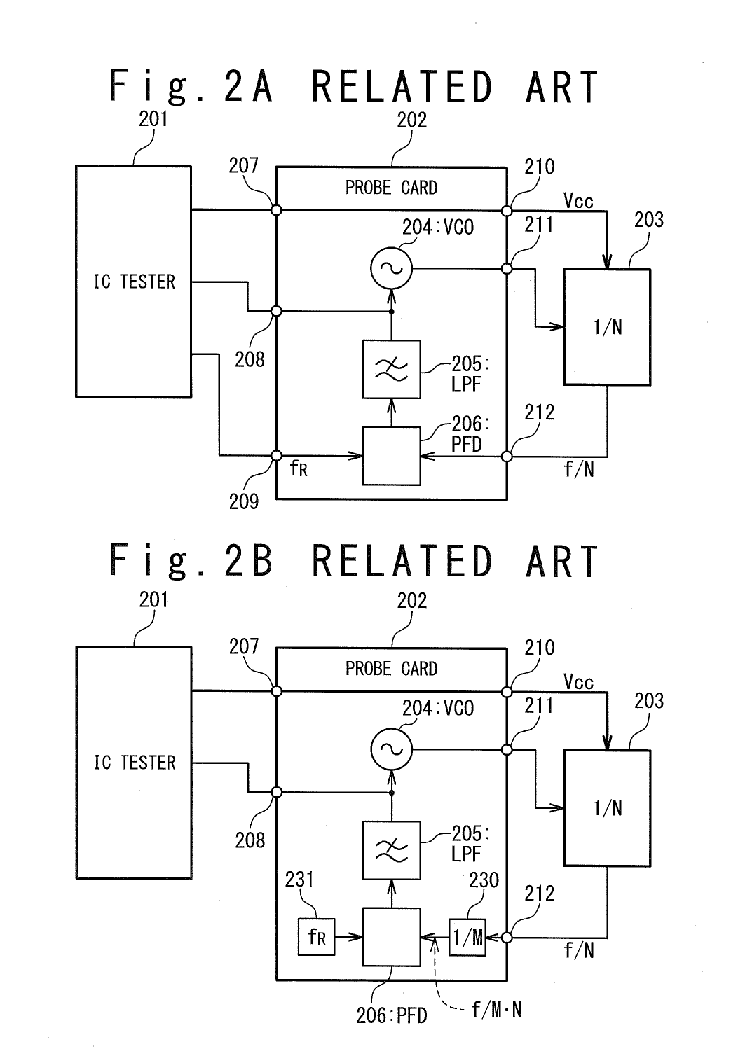

FIG. 3 is an overall view for describing a configuration of a semiconductor integrated circuit test device in a first embodiment according to the present invention;

FIGS. 4A to 4C are waveform charts for describing waveform of signals outputted from an LPF and a peak hold circuit section according to the present invention, wherein FIG. 4A shows the case where the prescaler to be measured normally operates, FIG. 4B shows the case where the prescaler to be measured abnormally operates and the peak hold circuit section outputs a DC voltage near a Vcc voltage, and FIG. 4C shows the case where the prescaler to be measured abnormally operates and the peak hold circuit section outputs a DC voltage near a GND voltage;

FIG. 5 is a conceptual view for describing relationship between points of an operational test and a normal operation range according to a semiconductor integrated circuit test method of the present invention;

FIG. 6 is a conceptual view for describing relationship between the points of the operational test, the normal operation range and a deficient operation mode according to the semiconductor integrated circuit test method of the present invention;

FIG. 7 is an overall view for describing a configuration of a semiconductor integrated circuit test device in a second embodiment according to the present invention;

FIG. 8A is an overall view for describing a configuration of a semiconductor integrated circuit test device in a third embodiment according to the present invention; and

FIGS. 8B to 8D are waveform charts for describing waveform of signals outputted from an LPF and a peak hold circuit section according to the present invention, wherein FIG. 8B shows the case where the prescaler to be measured normally operates, FIG. 8C shows the case where the prescaler to be measured abnormally operates and the peak hold circuit section outputs a DC voltage near a Vcc voltage, and FIG. 8D shows the case where the prescaler to be measured abnormally operates and the peak hold circuit section outputs a DC voltage near a GND voltage.

### DESCRIPTION OF PREFERRED EMBODIMENTS

Hereinafter, according to embodiments of the present invention will be described by referring to the accompanying drawings.

### First Embodiment

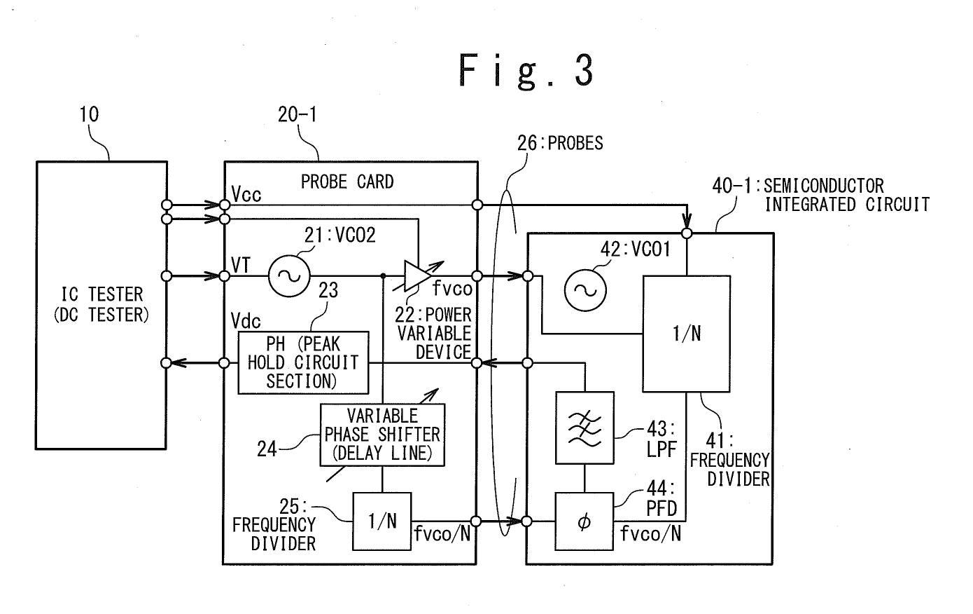

FIG. 3 is an overall view for describing a configuration of a semiconductor integrated circuit test device in a first embodiment according to the present invention. The semiconductor integrated circuit test device includes an IC tester 10 and a probe card 20-1.

First, a semiconductor integrated circuit 40-1 in the present embodiment will be described. It is assumed that a prescaler 41 to be measured having a PLL therein is connected to the semiconductor integrated circuit test device in the present embodiment. In other words, the semiconductor integrated circuit test device in the present embodiment intends to test the semiconductor integrated circuit 40-1 having a following configuration. That is, the semiconductor integrated circuit 40-1 in the present embodiment includes a plurality of input/output sections, a frequency divider 41 as a prescaler to be measured, a VCO 42, an LPF 43 and a PFD (Phase Frequency Detector) 44. Here, the PFD 44, the LPF 43 and the VCO 42 are connected to one another so as to form a feedback loop, and operate as a PLL.

When being connected to the probe card 20-1, the semiconductor integrated circuit 40-1 is set to a test mode. In the test mode, connection relationship between the components built in the semiconductor integrated circuit 40-1 changes and, in particular, connection relationship in the form of the feedback loop as the PLL is dissolved. The connection relationship between the components built in the semiconductor integrated circuit 40-1 in the test mode is as follows.

The first input/output section in the semiconductor integrated circuit 40-1 is connected to a first input section of the frequency divider 41. A second input/output section in the semiconductor integrated circuit 40-1 is connected to a second input section of the frequency divider 41. An output section of the frequency divider 41 is connected to a first input section of the PFD 44. An output section of the PFD 44 is connected to an input section of the LPF 43. An output section of the LPF 43 is connected to a third input/output section in the semiconductor integrated circuit 40-1. A fourth input/output section in the semiconductor integrated circuit 40-1 is connected to a second input section of the PFD 44. Since the VCO 42 does not need to operate in the test mode, it is not necessary to connect the VCO 42 to any component.

Next, a configuration of the probe card 20-1 in the present embodiment will be described. The probe card 20-1 in the present embodiment includes a plurality of input/output sections, a VCO 21, a power variable device 22, a peak hold circuit section 23, a variable phase shifter 24, a frequency divider 25 as a reference prescaler and a plurality of probes 26. Here, a delay line may be used as the variable phase shifter 24.

The IC tester 10 is connected to the first probe 26, a power supply section of the power variable device 22, a first input/output section of the voltage control oscillator 21 and a first input/output section of the peak hold circuit section 23 through the plurality of input/output section of the probe card 20-1. A second input/output section of the voltage control oscillator 21 is connected to an input section of the power variable device 22 and a first input/output section of the variable phase shifter 24. An output section of the power variable device 22 is connected to the second probe 26. A second input/output section of the peak hold circuit section 23 is connected to the third probe 26. A second input/output section of the variable phase shifter 24 is connected to a first input/output section of the frequency divider 25. A second input/output section of the frequency divider 25 is connected to the fourth probe 26.

An operation of each of the components of the semiconductor integrated circuit 40-1, the probe card 20-1 connected to the semiconductor integrated circuit 40-1 and the IC tester 10 connected to the probe card 20-1 in the test mode will be described.

First, the IC tester 10 applies a DC voltage VT as a first control signal to the VCO 21 of the probe card 20-1. The VCO 21 of the probe card 20-1 outputs a signal having a frequency fvco corresponding to the DC voltage VT outputted by the IC tester 10.

Here, the signal having the frequency fvco outputted from the VCO 21 is divided into two signals.

One of the two divided signals is supplied to the PFD 44 of the semiconductor integrated circuit 40-1 through the power variable device 22 of the probe card 20-1 and the frequency divider 41 of the semiconductor integrated circuit 40-1 in this order. The other of the two divided signals is also supplied to the PFD 44 of the semiconductor integrated circuit 40-1 through the variable phase shifter 24 of the probe card 20-1 and the frequency divider 25 of the probe card 20-1 in this order.

The power variable device 22 receives inputs of a second control signal from the IC tester 10 and the signal having the frequency fvco outputted from the VCO 21 and outputs a signal having the frequency fvco and predetermined power corresponding to the second control signal. The frequency divider 41 of the semiconductor integrated circuit 40-1 divides the frequency of the signal outputted from the power variable device 22 and outputs a signal having frequency fvco/N. A voltage Vcc is supplied from the IC tester 10 to the frequency divider 41 of the semiconductor integrated circuit 40-1 through the probe card 20-1.

The variable phase shifter 24 makes a predetermined change to the phase of a signal having the frequency fvco outputted from the VCO 21 and outputs the changed signal. The frequency divider 25 of the probe card 20-1 divides the frequency of the signal outputted from the variable phase shifter 24 and outputs a signal having frequency fvco/N. Accordingly, the frequencies of the two signals supplied to the PFD 44 of the semiconductor integrated circuit 40-1 are the same. However, the length of a path in which the signal outputted from the VCO 21 passes through the frequency divider 41 of the semiconductor integrated circuit 40-1 is not necessarily the same as the length of a path in which the signal outputted from the VCO 21 passes through the frequency divider 25 of the probe card 20-1. As a result, a phase difference between the two signals that reach PFD 44 can occur. The variable phase shifter 24 serves to compensate the phase difference. In other words, the phase difference corresponding to the difference in length between the paths in which the two signals inputted to the PFD 44 pass through is compensated by the variable phase shifter 24.

The PFD 44 receives inputs of a signal passing through the frequency divider 41 of the semiconductor integrated circuit 40-1 and a signal passing through the frequency divider 25 of the probe card 20-1, compares phases of the signals with each other and outputs a phase difference signal as a comparison result. The LPF 43 receives an input of the phase difference signal from the PFD 44, converts the signal into a DC voltage and outputs the DC voltage. The peak hold circuit section 23 receives an input of an output signal from the LPF 43, measures the DC voltage of the received signal and outputs a measurement result as a voltage Vdc to the IC tester 10.

The IC tester 10 can determine whether the prescaler of the semiconductor integrated circuit 40-1 to be measured normally operates or abnormally operates based on the voltage Vdc. This determination method will be described below.

First, when the prescaler of the semiconductor integrated circuit 40-1 to be measured normally operates, at both input sections of the PFD 44, phase relationship between the signal passing through the frequency divider 41 of the semiconductor integrated circuit 40-1 and the signal passing through the frequency divider 25 of the probe card 20-1 is constant at all times. Accordingly, the output of the PFD 44 is a constant pulse output at all times and the output of the LPF 43 receiving the output becomes a constant DC voltage. Even when the constant DC voltage is supplied to the peak hold circuit section 23, the output becomes an equal voltage. A value of the voltage outputted from the peak hold circuit section 23 to the IC tester 10 becomes an intermediate value between the Vcc voltage and the GND voltage, for example, about Vcc/2.

Next, when the prescaler of the semiconductor integrated circuit 40-1 to be measured abnormally operates, at the both input sections of the PFD 44, the phase difference between the signal passing through the frequency divider 41 of the semiconductor integrated circuit 40-1 and the signal passing through the frequency divider 25 of the probe card 20-1 varies. For this reason, the PFD 44 outputs a pulse signal varying according to the phase difference. The LPF 43 that receives an input of the pulse signal outputs a triangular wave. The peak hold circuit section 23 that receives an input of the triangular wave outputs a DC voltage near the Vcc voltage or the GND voltage.

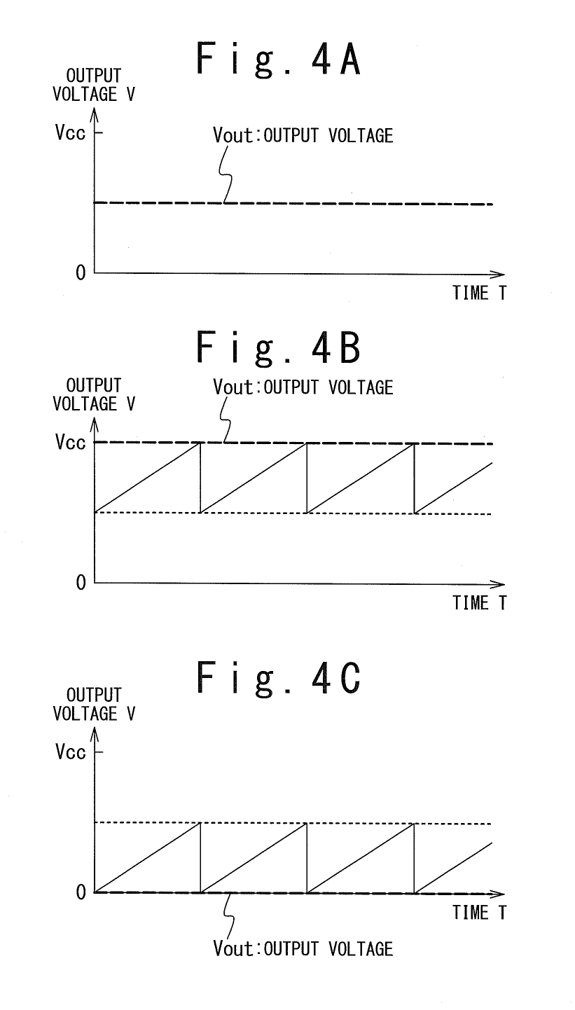

FIGS. 4A to 4C are waveform charts for describing waveform of the signals outputted from the LPF 43 and the peak hold circuit section 23 according to the present invention. In each of these waveform charts, a horizontal axis represents time and a vertical axis represents an output voltage. FIG. 4A shows the case where the prescaler of the semiconductor integrated circuit 40-1 to be measured normally operates. FIG. 4B shows the case where the prescaler of the semiconductor integrated circuit 40-1 to be measured abnormally operates and the peak hold circuit section 23 outputs a DC voltage near the Vcc voltage. FIG. 4C shows the case where the prescaler of the semiconductor integrated circuit 40-1 to be measured abnormally operates and the peak hold circuit section 23 outputs a DC voltage near the GND voltage.

To determine whether the prescaler of the semiconductor integrated circuit 40-1 to be measured operates normally or abnormally, it is desired that the output voltage of the LPF 43 is sufficiently away from both the Vcc voltage and GND voltage in the normal operation. In this sense, an ideal value of the output voltage of the LPF 43 in a normal operation is Vcc/2. However, since the output voltage of the LPF 43 is based on the phase difference between the two signals inputted to the PFD 44, the value of the output voltage is not necessarily about Vcc/2. Thus, the probe card 20-1 in the present embodiment can set the output voltage of the LPF 43 in the normal operation to about Vcc/2 by adjusting the phase difference to an appropriate value by use of the variable phase shifter 24.

As described above, the DC voltage of the output signal of the peak hold circuit section 23 varies depending on an operation state of the prescaler of the semiconductor integrated circuit 40-1 to be measured. Thus, according to the semiconductor integrated circuit test method in the present embodiment, by allowing the DC voltage to be reflected on a predetermined sorting standard, the quality of the prescaler of the semiconductor integrated circuit 40-1 to be measured is determined by use of the DC tester of the IC tester 10.

The semiconductor integrated circuit test device in the present embodiment can control the VCO 21 and the power variable device 22 by using the DC tester of the IC tester 10. That is, an operational test can be performed by individually changing frequency and power of the signal inputted to the frequency divider 41 of the prescaler of the semiconductor integrated circuit 40-1 to be measured.

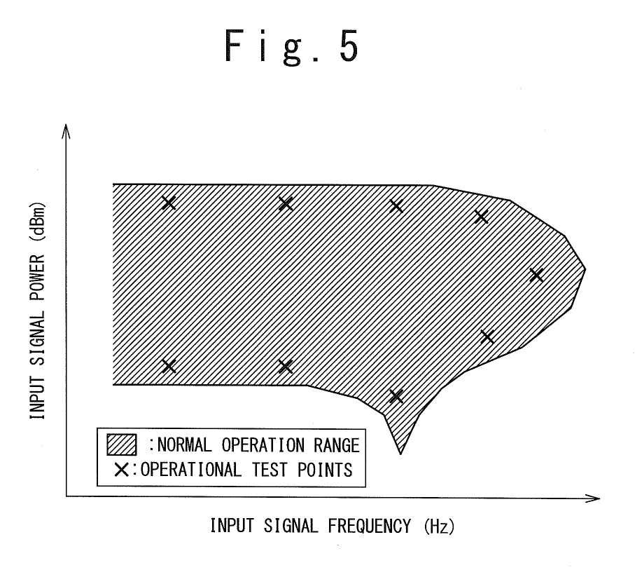

FIG. 5 is a conceptual view for describing relationship between points of the operational test and a normal operation range according to the semiconductor integrated circuit test method of the present invention. In this conceptual view, a horizontal axis represents frequency of an input signal and a vertical axis represents power of the input signal.

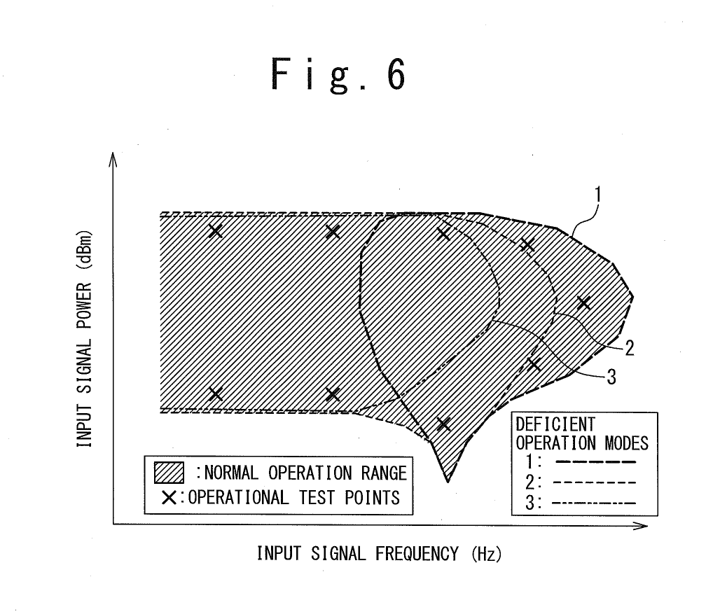

FIG. 6 is a conceptual view for describing relationship between the points of the operational test, the normal operation range and a deficient operation mode according to the semiconductor integrated circuit test method of the present invention. In this conceptual view, a horizontal axis represents frequency of an input signal and a vertical axis represents power of the input signal.

As described above, according to the semiconductor integrated circuit test method of the present invention, operation check of the prescaler of the semiconductor integrated circuit 40-1 to be measured can be performed at a plurality of points obtained by combining frequency and power of the input signal. As a result, the prescaler to be measured can be sorted corresponding to various deficient modes by using only the DC tester of the IC tester 10. That is, according to the present invention, defective pieces can be removed in an early stage in the on-wafer step.

### Second Embodiment

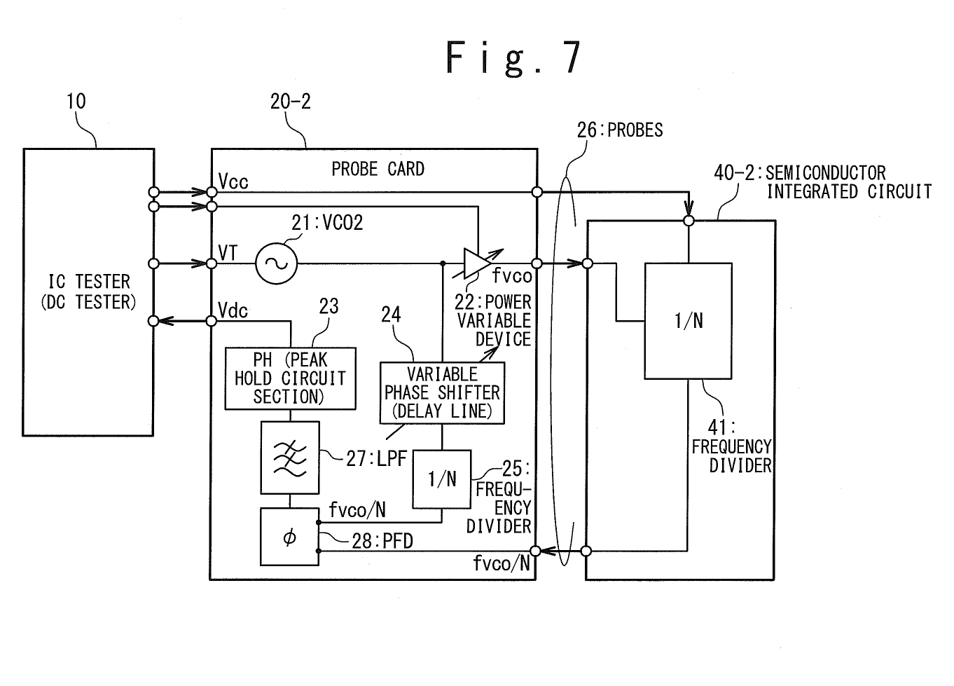

FIG. 7 is an overall view for describing a configuration of a semiconductor integrated circuit test device in a second embodiment according to the present invention. The semiconductor integrated circuit test device includes the IC tester 10 and a probe card 20-2.

The present embodiment is different from the first embodiment of the present invention in positions of a PFD 28 and an LPF 27. That is, in the first embodiment of the present invention, the prescaler of the semiconductor integrated circuit 40-1 to be measured includes the PFD 44 and the LPF 43. However, in the present embodiment, the probe card 20-2 includes the PFD 28 and the LPF 27 instead.

This means that in the present embodiment, even when a prescaler of the semiconductor integrated circuit 40-2 to be measured does not include a PLL circuit, a semiconductor integrated circuit test method can be performed as in the first embodiment of the present invention.

First, the semiconductor integrated circuit 40-2 in the present embodiment will be described. It is assumed that the prescaler of the semiconductor integrated circuit 40-2 to be measured that has no PLL therein is connected to the semiconductor integrated circuit test device in the present embodiment. In other words, the semiconductor integrated circuit 40-2 in the present embodiment intends to test the semiconductor integrated circuit 40-2 including the frequency divider 41 as the prescaler to be measured. The semiconductor integrated circuit 40-2 only needs to include the frequency divider 41 and a plurality of connection sections for connecting the plurality of probes 26.

Next, a configuration of the probe card 20-2 in the present embodiment will be described. The probe card 20-2 in the present embodiment is obtained by adding the PFD 28 and the LPF 27 to the probe card 20-1 in the first embodiment of the present invention. That is, the probe card 20-2 in the present embodiment includes a plurality of input/output sections, the VCO 21, the power variable device 22, the peak hold circuit section 23, the variable phase shifter 24, the frequency divider 25 as the reference prescaler and the plurality of probes 26.

A whole circuit obtained by connecting the probe card 20-2 to the prescaler of the semiconductor integrated circuit 40-2 to be measured in the present embodiment by the plurality of probes 26 is the same as the circuit obtained by connecting the probe card 20-1 to the prescaler of the semiconductor integrated circuit 40-1 to be measured in the first embodiment of the present invention. That is, the PFD 28 and the LPF 27 in the present embodiment correspond to the PFD 44 and the LPF 43 in the first embodiment of the present invention, respectively.

Since the other components of the semiconductor integrated circuit test device in the present embodiment, connection relationship between the components and operation of the components are the same as those in the first embodiment of the present invention, further detailed description thereof is omitted. Since the semiconductor integrated circuit test method using the semiconductor integrated circuit test device in the present embodiment is the same as that in the first embodiment of the present invention, further detailed description thereof is omitted.

In the present embodiment, even when the circuit to be measured is a single prescaler, a prescaler circuit that has the PLL therein without the test mode, or a prescaler circuit that has no PFD or LPF therein, as long as the circuit to be measured has input/output terminals of the prescaler circuit, operation check can be performed. That is, the present embodiment has higher versatility than the first embodiment of the present invention.

### Third Embodiment

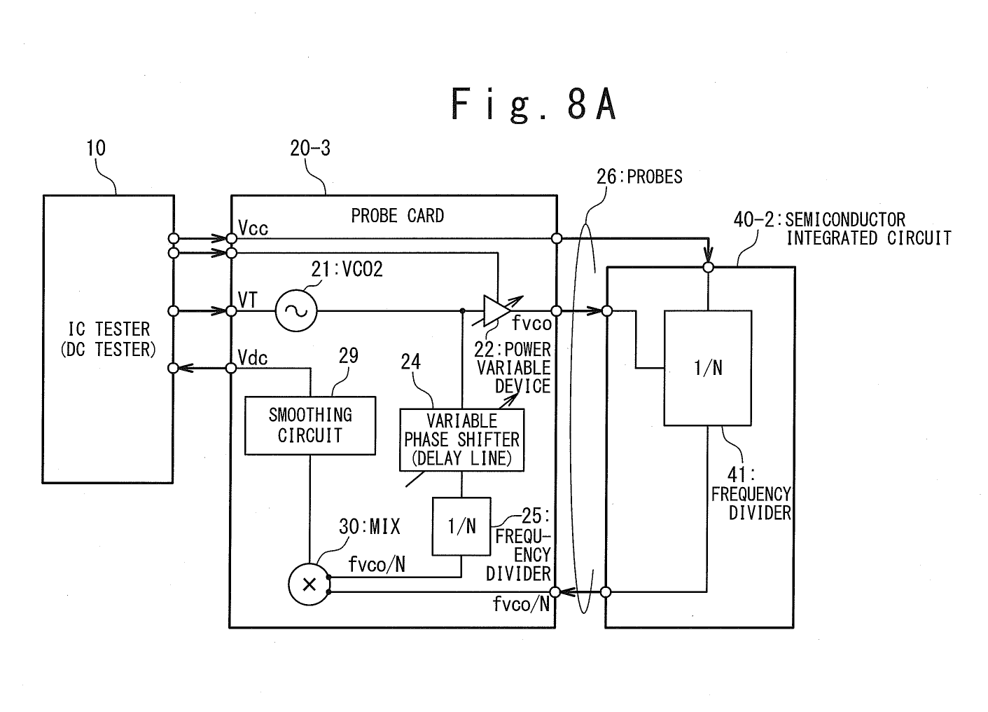

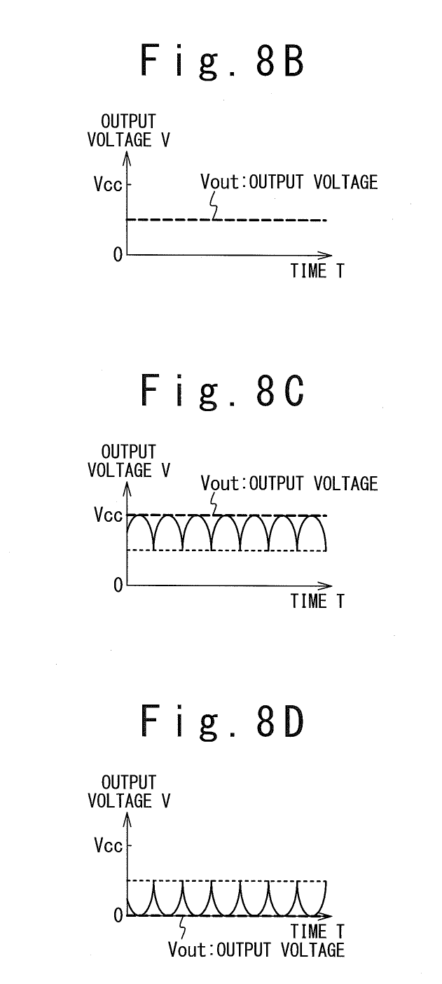

FIG. 8A is an overall view for describing a configuration of a semiconductor integrated circuit test device in a third embodiment according to the present invention. This semiconductor integrated circuit test device includes the IC tester 10 and a probe card 20-3.

The present embodiment is different from the second embodiment of the present invention mainly in a section from outputs of the two frequency dividers 41, 25 in the circuits of the probe cards 20-2, 20-3 to the input of the IC tester 10. This section includes a phase comparison circuit section that compares phases of the two signals with each other and outputs a signal based on a phase difference and a conversion circuit section that converts the output signal of the phase comparison circuit section into a DC voltage. That is, the probe card 20-2 in the second embodiment of the present invention includes the PFD 28 and the LPF 27 as the phase comparison circuit section, while the probe card 20-3 in the present embodiment includes a MIX (MIXer: mixer circuit) 30 alternatively. In addition, the probe card 20-2 in the second embodiment of the present invention includes the peak hold circuit section 23 as the conversion circuit section, while the probe card 20-3 in the present embodiment includes a smoothing circuit 29 instead. An integrator can be used as the smoothing circuit 29.

First, the semiconductor integrated circuit 40-2 in the present embodiment will be described. The semiconductor integrated circuit 40-2 in the present embodiment is the same as the semiconductor integrated circuit 40-2 in the second embodiment of the present invention. Further detailed description of the semiconductor integrated circuit 40-2 in the present embodiment is omitted.

Next, a configuration of the probe card 20-3 in the present embodiment will be described. As described above, the probe card 20-3 in the present embodiment is obtained by removing the PFD 28 and the LPF 27 as the phase comparison circuit section and the peak hold circuit section 23 as the conversion circuit section from the probe card 20-2 in the second embodiment of the present invention and adding the MIX 30 as the phase comparison circuit section and the smoothing circuit 29 as the conversion circuit section alternatively.

An output section of the frequency divider 41 of the semiconductor integrated circuit 40-2 and an output section of the frequency divider 25 of the probe card 20-3 are connected to two input sections of the MIX 30. That is, the MIX 30 receives inputs of an output signal from the frequency divider 41 of the semiconductor integrated circuit 40-2 and an output signal from the frequency divider 25 of the probe card 20-3. On the other hand, an input section of the smoothing circuit 29 is connected to an output section of the MIX 30. The input section of the IC tester 10 is connected to an output section of the smoothing circuit 29.

Since the other components of the semiconductor integrated circuit test device in the present embodiment and connection relationship between the components are the same as those in the first embodiment of the present invention, further detailed description thereof is omitted.

A semiconductor integrated circuit test method using the semiconductor integrated circuit test device in the present embodiment will be described. According to the semiconductor integrated circuit test method in the present embodiment, a phase of the output signal from the frequency divider 41 of the semiconductor integrated circuit 40-2 is compared with a phase of the output signal from the frequency divider 25 of the probe card 20-3 by the MIX 30. Next, an output signal of the MIX 30 is DC converted by the smoothing circuit 29. Since the other steps in this embodiment are the same as those in the second embodiment of the present invention, description thereof is omitted.

As compared to the second embodiment of the present invention, advantages of the present embodiment will be further described in detail. The case is considered where a frequency division ratio N of the prescaler circuit is small in high frequencies such as a GHz band. In this case, since a frequency fout of the output signal of the prescaler becomes high, phase comparison by use of a general PFD is difficult.

For example, when it is attempted to check the 2 frequency divider with N=2 in the 4 GHz band, phase comparison needs to be performed in the 2 GHz band. However, the general phase comparator only operates up to about a few dozens of MHz. For this reason, normal measurement is difficult.

In such case, as in the prescaler 20-3 in the present embodiment, when the phases of the two output signals from the two frequency dividers 41, 25 are compared to each other by the MIX 30 and the output signal of the MIX 30 is DC converted by the smoothing circuit 29, even if the output signal of the frequency divider still has a high frequency, an operation test of the prescaler can be achieved.

Determination of the quality of the semiconductor integrated circuit according to the semiconductor integrated circuit test method in the present embodiment will be described. When the semiconductor integrated circuit 40-2 is a non-defective piece, the DC voltage outputted from the smoothing circuit 29 becomes an intermediate voltage between the GND voltage and the Vcc voltage. On the contrary, when the semiconductor integrated circuit 40-2 is a defective piece, the DC voltage outputted from the smoothing circuit 29 becomes a voltage near the GND voltage or the Vcc voltage.

That is, a standard for determining the quality of the semiconductor integrated circuit in the present embodiment is the same that in the first or second embodiment of the present invention. Therefore, also in the present embodiment, it is preferred to set the MIX 30 so that the DC voltage outputted from the smoothing circuit 29 in the case where the semiconductor integrated circuit 40-2 is the non-defective piece is about Vcc/2.

In summary, according to the semiconductor integrated circuit test device of the present invention and the semiconductor integrated circuit test method using this device, the inexpensive DC tester 10 can be used as the IC tester. Further, by mounting the DC controllable VCO 21 and the power variable device 22 on the probe cards 20-1 to 20-3, the operation check of an input sensitivity characteristic as a basic characteristic of the prescaler circuit can be performed at multiple points rather than one point as conventional. Furthermore, sorting corresponding to various deficient modes can be performed in the on-wafer state by using the DC tester.

The embodiments of the present invention described above can be combined as necessary within a range that has no contradiction.

What is claimed is:

1. A semiconductor integrated circuit test device comprising:
an IC tester configured to provide a first and a second control signals based on a condition for determining a quality of a prescaler of a semiconductor integrated circuit to be sorted; and
a probe card connected to said IC tester and configured to connect with said semiconductor integrated circuit,
wherein said probe card comprises:
a VCO (Voltage Controlled Oscillator) configured to output a signal with a given frequency based on said first control signal;
a reference prescaler configured to divide said given frequency of said signal outputted from said VCO;
a power variable device configured to provide a signal with said given frequency and a given power based on said second control signal to said prescaler to be sorted;
a variable phase shifter configured to cancel a difference of phase based on a difference between a length of a path in which a signal passes through said reference prescaler and a length of a path in which a signal passes through said prescaler to be sorted; and
a conversion circuit section configured to convert a signal based on a difference of phase between a signal with a frequency divided by said prescaler to be sorted and a signal outputted from said reference prescaler, into a DC voltage and output said DC voltage to said IC tester.

2. The semiconductor integrated circuit test device according to claim 1, wherein said variable phase shifter comprises a delay line.

3. The semiconductor integrated circuit test device according to claim 1, wherein said probe card further comprises a phase comparison circuit section configured to compare a phase of an output signal of said prescaler to be sorted with a phase of an output signal of said reference prescaler and output a signal based on said difference of phases.

4. The semiconductor integrated circuit test device according to claim 3, wherein said phase comparison circuit section comprises:
a PFD (Phase Frequency Detector) configured to input said output signal of said prescaler to be sorted and said output signal of said reference prescaler; and
a LPF (Low Pass Filter) connected to an output side of said PFD.

5. The semiconductor integrated circuit test device according to claim 3,
wherein said phase comparison circuit section comprises a mixer circuit configured to input said output signal of said prescaler to be sorted and said output signal of said reference prescaler,
wherein said conversion circuit section comprises a smoothing circuit configured to convert an output signal of said mixer circuit into a DC voltage.

6. The semiconductor integrated circuit test device according to claim 5, wherein said smoothing circuit comprises an integrator.

7. A semiconductor integrated circuit testing method comprising:
connecting a probe card with a semiconductor integrated circuit including a prescaler to be sorted;
providing a first and a second control signal based on a condition for determining a quality of said prescaler to be sorted to said probe card;
outputting a signal with a given frequency based on said first control signal;
dividing the given frequency of said outputted signal by use of a reference prescaler of said probe card;
providing a signal with said given frequency and a given power based on said second control signal to said prescaler to be sorted;
dividing the given frequency of said provided signal by use of said prescaler to be sorted;
cancelling a difference of phase based on a difference between a length of a path in which a signal passes through said reference prescaler and a length of a path in which a signal passes through said prescaler to be sorted; and
converting a signal based on a difference of phase between a signal with a frequency divided by said prescaler to be sorted and a signal outputted from said reference prescaler, into a DC voltage.
